(19) United States
(12) Patent Application Publication
(10) Pub. No.: US 2025/0178888 A1
(43) Pub. Date: Jun. 5, 2025

(54) METHOD FOR PRODUCING A COMPOSITE CAP ELEMENT, AND COMPOSITE CAP ELEMENT

(71) Applicants: SCHOTT AG, Mainz (DE); SCHOTT PRIMOCELER OY, Tampere (FI)

(72) Inventors: Jonas DIMROTH, Frankfurt (DE); Jens Ulrich THOMAS, Mainz (DE); Volker SEIBERT, Ingelheim (DE); Axel OHLINGER, Wiesbaden (DE); Antti MÄÄTTÄNEN, Tampere (FI)

(73) Assignees: SCHOTT AG, Mainz (DE); SCHOTT PRIMOCELER OY, Tampere (FI)

(21) Appl. No.: 18/845,027

(22) PCT Filed: Apr. 25, 2023
(86) PCT No.: PCT/EP2023/060708

§ 371 Date: Sep. 9, 2024

(30) Foreign Application Priority Data
May 4, 2022 (DE) 10 2022 110 988.7

(51) Int. Cl. B81B 7/00; B81C 1/00

(52) U.S. Cl. CPC B81B 7/0067; B81C 1/00436; B81B 2207/09

(57) ABSTRACT

A method for producing a composite cap element for encapsulation of a MEMS component includes providing a base substrate having a window formed through an opening, providing a transparent cover substrate for transparently covering the window in the base substrate, producing a hermetic connection between the base substrate and the cover substrate in a connection region which extends peripherally around the window, heating the interconnected substrates in an edge region of the window to a temperature at which the base substrate becomes deformable and the cover substrate remains dimensionally stable, and displacing the dimensionally stable cover substrate in the region of the window while simultaneously deforming the deformable base substrate in a region around the window. A composite cap element is also provided.

The invention relates to a process for producing a composite cap element, especially for the encapsulation of a MEMS component, for example a MEMS mirror, and to a corresponding composite cap element.

In the production of microsystems, the production of the housing plays a major role since it determines the construction of the system and the protection thereof from mechanical, chemical and other influences during processing and operation.

A frequently employed method is what is called wafer level packaging (WLP), in which particular process steps are conducted even before the wafer is cut up.

In the production of housings for microsystems having moving parts, especially of microelectromechanical systems (MEMS) or microoptoelectromechanical systems (MOEMS), for example accelerometers, gyroscopes or micromirrors, cap elements with defined cavities are frequently used.

In the encapsulation of optoelectronic microsystems, cap elements with optically transparent elements may be used. In this case, there sometimes exist high demands on the surface and geometric properties, and hermetic encapsulation is desirable in many cases.

Furthermore, in the case of production of a multitude of cap elements, high uniformity of the individual elements may be desirable, especially over the whole area of the wafer.

In the case of high-efficiency MEMS mirrors for scanning applications, for example light projection or LiDAR devices or XR devices, it is also frequently the aim to achieve housing geometries that reduce parasitic reflections that would lead to image artifacts.

It is an object of the present invention to specify a process for producing a composite cap element, especially for the encapsulation of a MEMS component, for example a MEMS mirror, and a corresponding composite cap element, which enables high-precision manufacture, especially enables high precision of shaping, high precision of alignment and/or high precision of bonding of transparent elements, especially in order to achieve high uniformity and optical quality, and also enables efficient and scalable production, which especially makes it possible to reduce the number of process steps, especially reprocessing steps.

The object is achieved by the subject matter of the independent claims.

Advantageous embodiments are defined in the dependent claims.

The invention relates to a process for producing a composite cap element, especially for the encapsulation of a MEMS component, for example a MEMS mirror.

The process comprises the providing of a base substrate having at least one window, formed by an opening within the base substrate, and the providing of a transparent cover substrate for transparent coverage of the at least one window in the base substrate.

The base substrate and the cover substrate have different softening temperatures, where the softening temperature of the base substrate is lower than the softening temperature of the cover substrate.

The process further comprises the creating of a bond, especially a hermetic bond, between the base substrate and the cover substrate in a connection region formed at least around the circumference of the window, in order to hermetically seal the window.

The process further comprises the heating of the mutually bonded substrates at least in an edge region of the window to a temperature at which the base substrate becomes deformable and the cover substrate remains dimensionally stable.

In addition, the process comprises the moving of the dimensionally stable cover substrate in the region of the window with simultaneous deformation of the deformable base substrate in a region around the window in order to form the composite cap element.

As described, the base substrate and the cover substrate have different softening temperatures. What is meant in particular by softening temperature in the context of the present invention is a temperature from which the respective substrate becomes deformable. This preferably means that temperature at which the respective substrate reaches a viscosity of 10^{7.6} dPas (decipascal seconds).

As described, in the context of the process described, the mutually bonded substrates are heated to a temperature at which the base substrate becomes deformable, but the cover substrate remains dimensionally stable. In particular, the mutually bonded substrates may be heated to a temperature at which the base substrate reaches a viscosity of below 10¹³ Pas (pascal seconds), preferably to a temperature at which the base substrate reaches a viscosity of below 10¹² Pas (pascal seconds), more preferably to a temperature at which the base substrate reaches a viscosity of below 10¹¹ Pas (pascal seconds), even more preferably to a temperature at which the base substrate reaches a viscosity of below 10⁹ Pas (pascal seconds), even more preferably to a temperature at which the base substrate reaches a viscosity of below 10⁸ Pas (pascal seconds), and where the cover substrate retains a higher viscosity, especially a higher viscosity by at least 10¹ Pas or else 10² Pas.

In particular, the mutually bonded substrates are heated to a temperature above the softening temperature of the base substrate and below the softening temperature of the cover substrate.

In principle, the sequence in time of the aforementioned process steps is not fixed. However, it is preferably the case that the creating of the hermetic bond between the base substrate and the cover substrate precedes the heating of the mutually bonded substrates and/or precedes the moving of the cover substrate in the region of the window with simultaneous deformation of the base substrate in a region around the window.

The hermetic bond which is established between the base substrate and the cover substrate can be established in various ways.

For example, the hermetic bond between the base substrate and the cover substrate may be formed by laser welding and/or in such a way that the circumferential connection region around the window is linear.

However, the hermetic bond may also be formed by anodic bonding and/or in such a way that the circumferential connection region around the window is two-dimensional.

As described, in the process, the window present in the base substrate is closed by the transparent cover substrate. The cover substrate, especially in the region of the window, is placed onto the base substrate with a border overlapping the base substrate.

In this case, an area, especially an annular area, of the cover substrate comes into contact with an area, especially an annular area, of the base substrate.

Preferably, at least the areas of the two substrates that come into contact with one another, or else the substrates as a whole, are in flat or planar form.

In particular, it may be the case that at least regions of the base substrate are two-dimensional, especially planar, and/or at least regions of the transparent cover substrate are two-dimensional, especially planar.

Because the window in the base substrate is covered by the cover substrate, the transparent cover substrate thus preferably comes into two-dimensional contact with the base substrate within a contact region around the at least one window.

This contact region may have a width, especially around the circumference of the window, of at least 10 μm, preferably of at least 50 μm, more preferably of at least 800 μm.

In a preferred embodiment, there is a bond quality index Q between the base substrate and the cover substrate of not less than 0.8, preferably not less than 0.9, even more preferably not less than 0.95.

The bond quality index Q is Q=1−(A−G)/A where A denotes the area of the contact region between the base substrate and the cover substrate and G denotes a good area within which the distance between the substrates is less than 5 μm, preferably less than 2 μm, even more preferably less than 1 μm, even more preferably less than 0.3 μm.

Depending on whether the cover substrate already has a desired dimension when laid onto the base substrate or a desired dimension is created only after it has been laid on, there may optionally be a process step in order to adjust the dimension of the cover substrate.

In particular, the process comprises, in some process variants, the introducing of a dividing channel that crosses the cover substrate and runs around the circumference of the at least one window in the base substrate.

The dividing channel may especially be introduced into the cover substrate after the hermetic bond between the base substrate and the cover substrate has been created.

The dividing channel may preferably run around the circumference of the connection region, especially around the circumference of a linear connection region (for example in the case of laser welding), or runs within the connection region, especially within a two-dimensional connection region (for example in the case of anodic bonding).

The dividing channel may be introduced into the cover substrate, for example, by laser ablation.

Particularly with regard to MEMS mirrors, but also independently thereof in principle, an oblique position of the cover substrate with respect to the base substrate may be desired in the final composite cap element.

Against this background, the process may especially be such that the moving of the cover substrate in the region of the window with simultaneous deformation of the base substrate in a region around the window is effected in such a way that the cover substrate assumes an oblique position relative to the base substrate in the region of the window.

Such an oblique position of the cover substrate in the region of the window may in particular have an angle between 1 degree and 45 degrees, preferably an angle between 10 degrees and 25 degrees.

A tool that may be used in order to perform the movement or deformation may be a ram that can act, for example, on the cover substrate or on the base substrate.

The moving of the cover substrate in the region of the window can thus be effected by means of a ram that exerts a pressure on the cover substrate in such a way that the base substrate is deformed in a region around the window.

Here, there may be optionally provided, opposite the ram, an opposing face against which the base substrate is pressed, for example in order to increase the bond quality index and/or strengthen the bond.

The moving of the cover substrate in the region of the window may alternatively or additionally be effected by means of a ram that exerts a pressure on the base substrate in the region around the window in such a way that the base substrate is deformed in the region around the window.

In turn, there may be optionally provided, opposite the ram, an opposing face against which the cover substrate is pressed. This opposing face may be formed, for example, by a further ram.

The ram and/or the opposing face may each take the form of a circumferential collar that in particular acts on the respective substrate in the region of the connection region and/or of the contact region. In this way, for example, an optically relevant region of the cover substrate may remain unaffected by the pressure.

In addition, it may be the case that the ram and/or the opposing face is/are heated, for example to increase the bond quality index and/or to strengthen the bond.

In one development of the invention, the cover substrate may have been coated, for example by means of an antireflection coating and/or by means of particular filter layers, for example for RGB or NIR transmission etc. Even in the case of such coatings, a ram in the form of a circumferential collar may be advantageous in order not to damage such layers.

As described above, the base substrate and the cover substrate have different softening temperatures.

The differing softening temperatures of the base substrate and of the cover substrate may, for example, differ from one another by at least 50 K, preferably by at least 100 K, more preferably by at least 150 K.

Alternatively or additionally, it may also be the case that the differing softening temperatures of the base substrate and of the cover substrate differ from one another in such a way that, at the softening temperature of the base substrate and/or at the softening temperature of the cover substrate, the viscosity of the two substrates differs by at least 10^{0.5} Pas, preferably by at least 10¹ Pas, more preferably by at least 10² Pas.

With regard to the materials, the base substrate may especially comprise or consist of one of the following materials: glass, especially borosilicate glass, soda-lime glass, alkali metal borosilicate glass, alkali metal borate glass, alkali metal phosphate glass, zinc borate glass, lead-containing glass, vanadate glass, zinc phosphate glass. However, it is also possible that the base substrate comprises or consists of at least one of the materials mentioned hereinafter for the cover substrate.

The cover substrate may especially comprise or consist of one of the following materials: glass, especially aluminosilicate glass, aluminoborosilicate glass, rare earth aluminosilicate glass, alkaline earth metal aluminosilicate glass, glass-ceramic, quartz glass, sapphire, silicon, germanium. However, it is also possible that the cover substrate comprises or consists of at least one of the materials mentioned above for the base substrate.

Some preferred embodiments are to be specified hereinafter.

In some embodiments, the bond strength, especially shear strength at room temperature, between the base substrate and the cover substrate is preferably at least 10 MPa.

In some embodiments, the coefficient of thermal expansion of the base substrate is between 2×10⁻⁶ K⁻¹ and 10×10⁻⁶ K⁻¹.

In some embodiments, the coefficient of thermal expansion of the cover substrate is between 2×10⁻⁶ K⁻¹ and 10×10⁻⁶ K⁻¹.

In some embodiments, the absolute value of the difference between the coefficients of thermal expansion of the base substrate and of the cover substrate is less than 5×10⁻⁶ K⁻¹, preferably less than 2×10⁻⁶ K⁻¹, more preferably less than 1×10⁻⁶ K⁻¹.

In some embodiments, the base substrate has a thickness of between 0.02 mm and 5 mm.

In some embodiments, the cover substrate has a thickness of between 0.02 mm and 5 mm.

In some embodiments, the at least one window in the base substrate has an area of between 0.5 mm×0.5 mm and 50 mm×50 mm.

In some embodiments, the cover substrate has a surface having an average roughness Rₐ of not more than 15 nm, preferably not more than 10 nm, more preferably not more than 5 nm.

In some embodiments, the cover substrate, especially an optically relevant part of the window, has a flatness of less than 20 μm.

In some embodiments, the cover substrate has a variation in thickness of less than 5%, especially of the average thickness across the area of the window.

In some embodiments, the cover substrate has transmittance for a wavelength between 300 nm and 2500 nm of at least 90%.

As described, the process comprises the providing of a base substrate having at least one window. In one development, however, several windows may also be provided in the base substrate.

Accordingly, the base substrate, in one development, may have a multitude of windows that are each formed by an opening within the base substrate, wherein the multitude of windows are preferably arranged in a regular pattern.

In that case, the transparent cover substrate may be intended for simultaneous coverage of the multitude of windows and/or a multitude of transparent cover substrates may be provided, each of which is intended to cover one or more windows.

Preferably, a hermetic bond between the base substrate and the cover substrate is created around the circumference of each of the windows, especially in that a linear connection region is created around each window, especially by laser welding, and/or in that a two-dimensional, for example full-area, connection region is created between the substrates, especially by anodic bonding.

The mutually bonded substrates are additionally preferably heated at least in the region of each window, for example gradually in the region of a particular window or more preferably simultaneously as a whole.

In addition, the cover substrates are preferably moved in the region of each window with simultaneous deformation of the base substrate, for example gradually in the region of a particular window or more preferably simultaneously as a whole, for which purpose, for example, it is possible to use a multitude of rams which in particular define a uniform oblique position for the multitude of movements or deformations.

The invention further relates to a process for producing an encapsulated MEMS component, comprising the providing of a carrier substrate having a MEMS component, for example an MEMS mirror, and further comprising the applying and bonding, especially hermetic bonding, of a composite cap element, especially of a composite cap element that has been produced as described above, atop the carrier substrate in such a way that the MEMS component is sealed, especially hermetically, between the carrier substrate and the composite cap element.

The invention further relates to a composite cap element for the encapsulation of a MEMS component, for example a MEMS mirror, produced or producible by the process as described above.

The invention further relates to a composite cap element for the encapsulation of a MEMS component, for example a MEMS mirror.

The composite cap element comprises a base substrate having at least one window, formed by an opening within the base substrate, and a transparent cover substrate that transparently covers the at least one window in the base substrate.

The composite cap element additionally comprises a bond, especially a hermetic bond, between the base substrate and the cover substrate in a connection region formed at least around the circumference of the window in such a way that the window is sealed, especially hermetically sealed.

The base substrate has a deformation in a region around the window in such a way that the cover substrate has been moved in its position relative to the base substrate.

Moreover, the base substrate and the cover substrate have different softening temperatures, where the softening temperature of the base substrate is lower than the softening temperature of the cover substrate.

The hermetic bond between the base substrate and the cover substrate may be linear, especially in the form of a laser weld seam.

The hermetic bond between the base substrate and the cover substrate may be two-dimensional, especially in the form of an anodic bond.

At least regions of the base substrate are two-dimensional, especially planar. In addition, at least regions of the transparent cover substrate are two-dimensional, especially planar.

The transparent cover substrate is preferably in two-dimensional contact with the base substrate within a contact region around the at least one window in order to transparently cover the at least one window in the base substrate.

The contact region may have a width, especially around the circumference of the window, of at least 10 μm, preferably of at least 50 μm, more preferably of at least 800 μm.

There is in particular a bond quality index Q between the base substrate and the cover substrate of not less than 0.8, preferably not less than 0.9, even more preferably not less than 0.95.

The bond quality index Q is Q=1−(A−G)/A where A denotes the area of the contact region between the base substrate and the cover substrate and G denotes a good area within which the distance between the substrates is less than 5 μm, preferably less than 2 μm, even more preferably less than 1 μm, even more preferably less than 0.3 μm.

The composite cap element may further comprise a dividing channel that crosses the cover substrate and runs around the circumference of the at least one window.

The dividing channel preferably runs around the circumference of the connection region, especially around the circumference of the linear connection region, or runs within the connection region, especially within the two-dimensional connection region.

The deformation of the base substrate is preferably such that the cover substrate has an oblique position relative to the base substrate in the region of the window, wherein the oblique position of the cover substrate in the region of the window in particular has an angle between 1 degree and 45 degrees, preferably an angle between 10 degrees and 25 degrees.

The differing softening temperatures of the base substrate and of the cover substrate may differ from one another by at least 50 K, preferably by at least 100 K, more preferably by at least 150 K.

The base substrate may especially comprise or consist of one of the following materials: glass, especially borosilicate glass, soda-lime glass, alkali metal borosilicate glass, alkali metal borate glass, alkali metal phosphate glass, zinc borate glass, lead-containing glass, vanadate glass, zinc phosphate glass.

The cover substrate may especially comprise or consist of one of the following materials: glass, especially aluminosilicate glass, aluminoborosilicate glass, rare earth aluminosilicate glass, alkaline earth metal aluminosilicate glass, glass-ceramic, quartz glass, sapphire, silicon, germanium.

The bond strength, especially shear strength at room temperature, between the base substrate and the cover substrate may be at least 10 MPa.

The coefficient of thermal expansion of the base substrate may be between 2×10⁻⁶ K⁻¹ and 10×10⁻⁶ K⁻¹.

The coefficient of thermal expansion of the cover substrate may be between 2×10⁻⁶ K⁻¹ and 10×10⁻⁶ K⁻¹.

The absolute value of the difference between the coefficients of thermal expansion of the base substrate and of the cover substrate may be less than 5×10⁻⁶ K⁻¹, preferably less than 2×10⁻⁶ K⁻¹, more preferably less than 1×10⁻⁶ K⁻¹.

The base substrate may have a thickness of between 0.02 mm and 5 mm.

The cover substrate may have a thickness of between 0.02 mm and 5 mm.

The at least one window in the base substrate may have an area of between 0.5 mm×0.5 mm and 50 mm×50 mm.

The cover substrate may have a surface having an average roughness Rₐ of not more than 15 nm, preferably not more than 10 nm, more preferably not more than 5 nm.

The cover substrate, especially an optically relevant part of the window, may have a flatness of less than 20 μm.

The cover substrate may have a variation in thickness of less than 5%, especially of the average thickness across the area of the window.

The cover substrate may have a transmittance for a wavelength between 300 nm and 2500 nm of at least 90%.

The base substrate may have a multitude of windows that are each formed by an opening within the base substrate and wherein the multitude of windows are preferably arranged in a regular pattern.

The transparent cover substrate may simultaneously cover the multitude of windows and/or a multitude of transparent cover substrates may be included, each of which covers one or more windows.

A hermetic bond between the base substrate and the cover substrate around the circumference of each of the windows is preferably included.

The base substrate preferably has a deformation in a region around each of the windows such that the cover substrates have been moved in their position relative to the base substrate.

The invention further relates to an encapsulated MEMS component comprising a carrier substrate having a MEMS component, for example a MEMS mirror, and a composite cap element, especially according to the above description, that has been applied and bonded, especially hermetically bonded, atop the carrier substrate in such a way that the MEMS component is sealed, especially hermetically sealed, between the carrier substrate and the composite cap element.

The invention is elucidated in detail hereinafter by figures. The figures show:

FIG. 1, 2 a schematic top view of a base substrate with a window and a cover substrate,

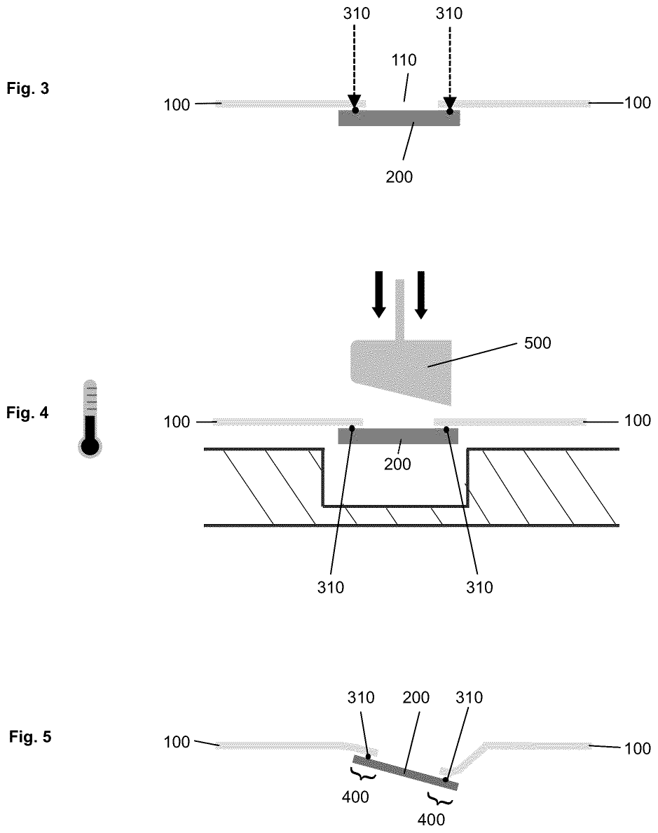

FIG. 3-5 a schematic section view of a first illustrative sequence of process steps for production of a composite cap element,

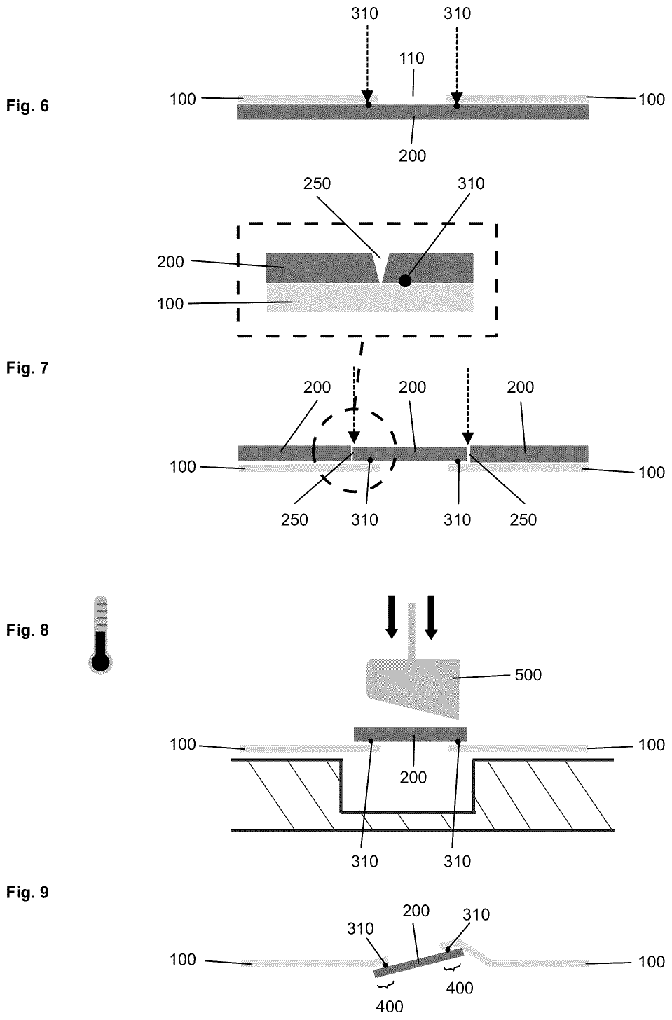

FIG. 6-9 a schematic section view of a second illustrative sequence of process steps for production of a composite cap element,

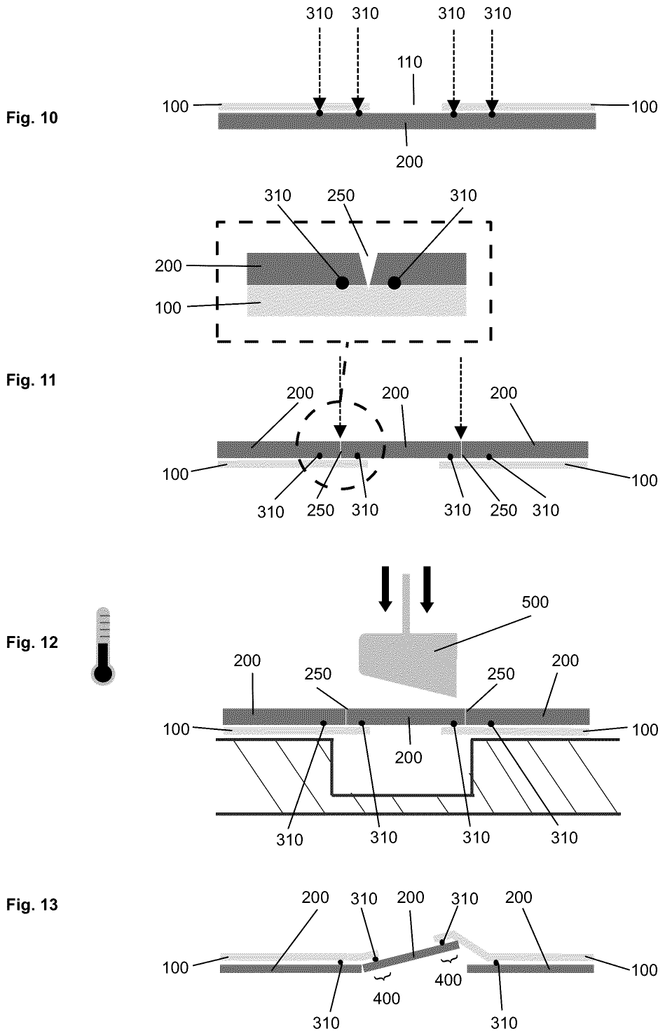

FIG. 10-13 a schematic section view of a third illustrative sequence of process steps for production of a composite cap element,

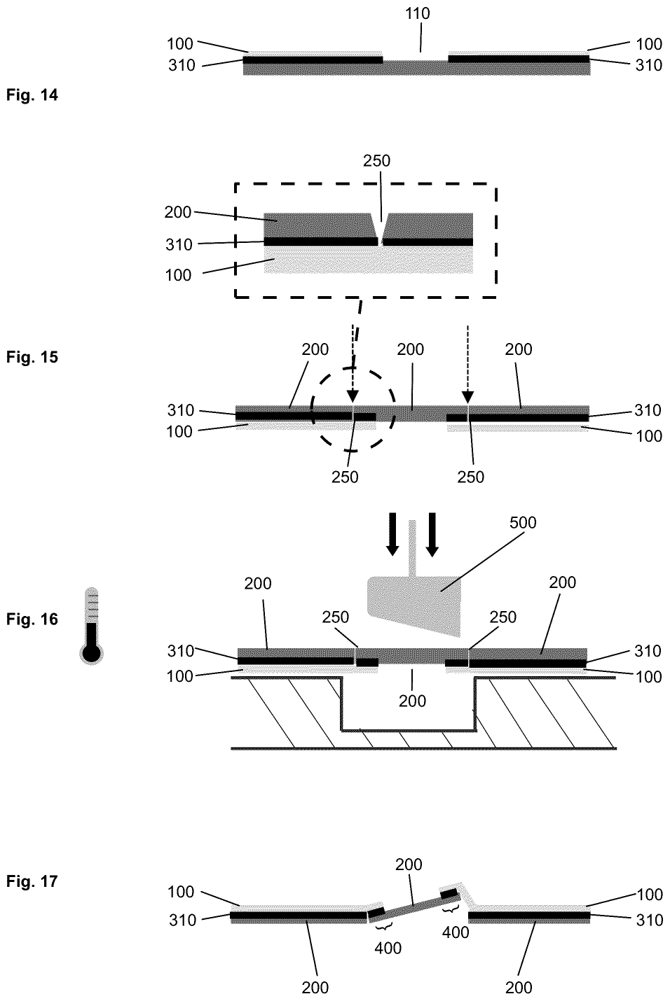

FIG. 14-17 a schematic section view of a fourth illustrative sequence of process steps for production of a composite cap element,

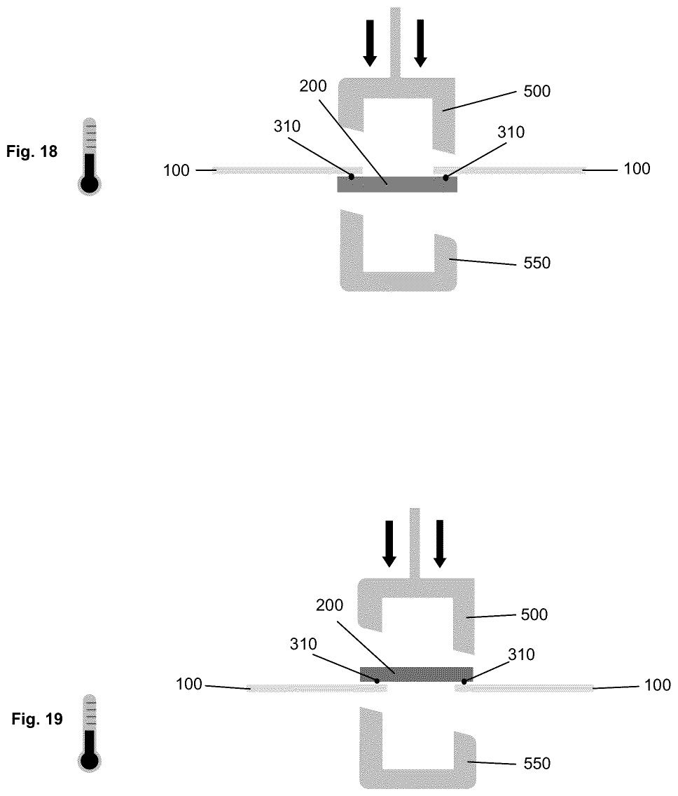

FIG. 18, 19 a schematic section view of alternative process steps of deformation with a ram and an opposing face,

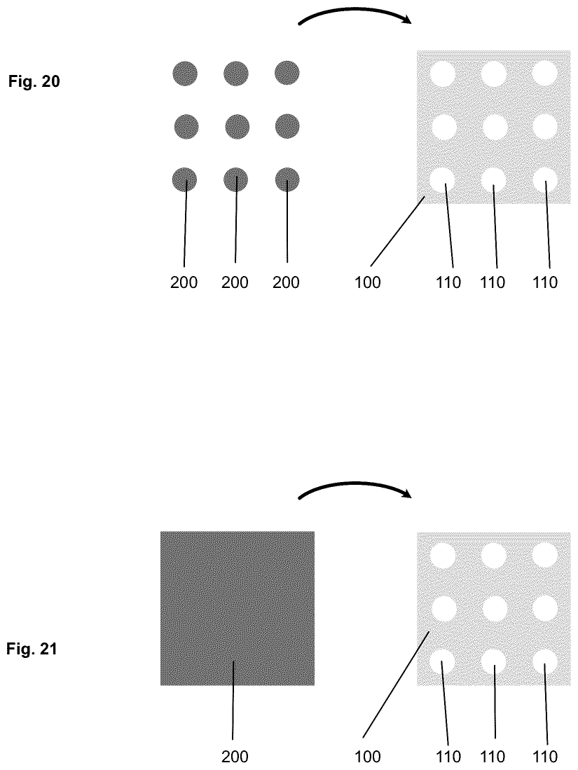

FIG. 20, 21 a schematic top view of a base substrate with a multitude of windows and one or more cover substrates for coverage of the windows.

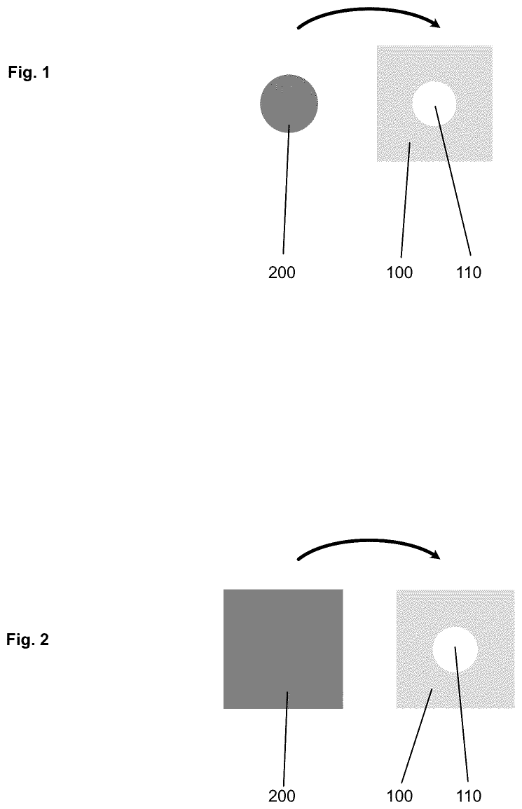

FIGS. 1, 2 each show a base substrate 100 with a window 110 and a cover substrate 200 placed onto the base substrate. In FIG. 1, the cover substrate 200 is already matched to the geometry of the window 110. However, the cover substrate 200 is somewhat larger than the window 110 present in the base substrate 110, and so the window 110 is fully covered, and an overlap of the two substrates around the circumference of the window 110 is formed, within which the substrates can be bonded in a next step. In FIG. 2, the cover substrate 200 has a geometry like the base substrate 100 and hence covers it completely.

FIGS. 3-5 show a first illustrative sequence of process steps for production of a composite cap element.

In the process step shown in FIG. 3, a bond 310 is established between the base substrate 100 and the cover substrate 200 that has been brought into contact therewith, for example according to FIG. 1, in this case by laser welding for example. The bond 310 is formed around the circumference of the window 110 in such a way that the window 110 is hermetically sealed by the cover substrate 200.

In the process step shown in FIG. 4, the mutually bonded substrates have been or are heated, attaining a temperature at which the base substrate 100 becomes deformable but the cover substrate 200 remains dimensionally stable. A ram 500 that has an oblique ram surface relative to the base substrate 100 is used to conduct a hot forming operation. This exerts a pressure on the deformable base substrate 100 in a region around the circumference of the window 110 comprising the bond 310, in order to deform the edge region of the base substrate 110 around the circumference of the window 110 and at the same time to move the cover substrate 200 secured thereon into an oblique position with respect to the base substrate 100.

FIG. 5 shows the composite cap element thus obtained with a contact region 400 around the circumference of the window 110, comprising the linear bond 310 within which the two substrates are in contact with one another and preferably have a bond quality index Q of not less than 0.8.

FIGS. 6-9 show a second illustrative sequence of process steps for production of a composite cap element, where this sequence is similar in some aspects to the first sequence and differs in other aspects.

In the process step shown in FIG. 6, a hermetic bond 310 around the circumference of the window 110 is established between a base substrate 100 and a cover substrate 200 placed over the full area, for example according to FIG. 2, in this example again by laser welding.

In the process step shown in FIG. 7, a dividing channel 250 is introduced, which crosses the cover substrate 200 and runs around the circumference of the window 110, for example by laser ablation. The dividing channel 250 runs around the circumference of the linear bond 310. In this way, the geometry of the cover substrate 200 is matched to the geometry of the window 110, and any excess outer portion of the cover substrate 200 can be discarded.

In the process step shown in FIG. 8, the mutually bonded substrates have been or are heated in turn in order to conduct hot forming by means of the ram 500. In this example, the ram 500 exerts a pressure on the dimensionally stable cover substrate 200 in order to move the cover substrate 200 into an oblique position and at the same time to draw out an edge region of the deformable base substrate 100 around the circumference of the window 110 and hence to form the composite cap element shown in FIG. 9.

FIGS. 10-13 show a third illustrative sequence of process steps for production of a composite cap element, where this sequence is similar in some aspects to the first or second sequence and differs in other aspects.

In the process step shown in FIG. 10, a first hermetic bond 310 around the circumference of the window 110 is established between a base substrate 100 and a cover substrate 200 placed over the full area, for example according to FIG. 2. In addition, in this example, a second circumferential hermetic bond 310 is established between the substrates, where both bonds 310 are established as linear bonds by laser welding. The second bond runs around the circumference of the first bond.

In the process step shown in FIG. 11, a dividing channel 250 which crosses the cover substrate 200 and runs around the circumference of the window 110 is introduced, wherein the dividing channel is introduced between the first and second circumferential bonds 310. This firstly defines the geometry of the cover substrate 200 for the window 110 to be pulled out, and at the same time bonds an outer portion of the cover substrate 200 to the base substrate.

In the process step shown in FIG. 12, the substrates have been or are heated in turn, and the inner portion of the dimensionally stable cover substrate 200 isolated from the outer portion by the dividing line 250 is moved by means of the ram 500 in order to produce the composite cap element shown in FIG. 13.

FIGS. 14-17 show a fourth illustrative sequence of process steps for production of a composite cap element, where this sequence is similar in some aspects to the first, second and third sequences and differs in other aspects.

In the process step shown in FIG. 14, a two-dimensional bond 310 is established between a base substrate 100 and a cover substrate 200 that has been placed over the full area, for example according to FIG. 2, in this example by anodic bonding. The bond 310 is established over the full area in this example, and hence especially also in a contact region 400 of the two substrates around the circumference of the window 110.

In the process step shown in FIG. 15, a dividing channel 250 which crosses the cover substrate 200 and runs around the circumference of the window 110 is introduced, wherein the dividing channel runs through the two-dimensional bond 310. The dividing channel 250 especially also extends transverse to the plane of the substrate through the region of the two-dimensional bond 310. This firstly defines an inner portion of the cover substrate 200 that covers the window 110, and an outer portion which is separated therefrom by the dividing line 250 and which, just like the inner portion, is bonded to the base substrate by the bond 310.

In the process step shown in FIG. 16, the substrates have been or are heated in turn, and the inner portion of the dimensionally stable cover substrate 200 is moved by means of the ram 500 in order to produce the composite cap element shown in FIG. 17.

FIGS. 18 and 19 show a development, particularly with regard to the movement and deformation step. The ram 500 here takes the form, for example, of a circumferential collar designed to exert the desired pressure on the circumferential contact region 400 between the substrates.

In this way, it is possible, for example, to improve the bond quality index. Moreover, especially in the case that the pressure is exerted on the cover substrate 200, as shown in FIG. 19, an inner portion, especially one of optical relevance, of the cover substrate 200 can be moved without contact with the ram 500.

As can likewise be seen, opposite the ram 500, an opposing face 550 may be provided, onto which the contact region 400 between the two substrates is pressed. The opposing face 550 in this example likewise takes the form of a circumferential collar. However, this should be considered merely to be illustrative. It is of course possible that the ram 500 and/or the opposing face 550 are of different shape.

FIGS. 20 and 21, similarly to FIGS. 1 and 2, each show a base substrate 100, but with a multitude of windows 110, and one or more cover substrates 200 for coverage of the windows. The above-described process procedures may be conducted proceeding from such substrates with a multitude of windows in each case as well, especially simultaneously.

1. A process for producing a composite cap element, especially for the encapsulation of a MEMS component, for example a MEMS mirror, comprising:
providing a base substrate having a window, formed by an opening within the base substrate,
providing a transparent cover substrate for transparent coverage of the window in the base substrate,
wherein the base substrate and the cover substrate have different softening temperatures and the softening temperature of the base substrate is lower than the softening temperature of the cover substrate,
creating a hermetic bond between the base substrate and the cover substrate in a connection region formed around the circumference of the window, to hermetically seal the window,
heating the mutually bonded substrates in an edge region of the window to a temperature at which the base substrate becomes deformable and the cover substrate remains dimensionally stable,
moving the dimensionally stable cover substrate in the region of the window with simultaneous deformation of the deformable base substrate in a region around the window in order to form the composite cap element.

2. The process of claim 1,
wherein the creating of the hermetic bond between the base substrate and the cover substrate precedes the heating of the mutually bonded substrates and/or precedes the moving of the cover substrate in the region of the window with simultaneous deformation of the base substrate in a region around the window.

3. The process of claim 1,
wherein the hermetic bond between the base substrate and the cover substrate is formed by laser welding, and/or
wherein the hermetic bond between the base substrate and the cover substrate is formed by anodic bonding.

4. The process of claim 1,
wherein regions of the base substrate are two-dimensional, and/or wherein regions of the transparent cover substrate are two-dimensional, and/or
wherein the transparent cover substrate is brought into two-dimensional contact with the base substrate within a contact region around the window in order to transparently cover the window in the base substrate, and
wherein the contact region has a width of at least 10 μm, and
wherein the bond between the base substrate and the cover substrate has a bond quality index Q of not less than 0.8,
wherein the bond quality index Q is defined as Q=1−(A−G)/A where A denotes the area of the contact region between the base substrate and the cover substrate and G denotes an area within which the distance between the substrates is less than 5 μm.

5. The process of claim 1, further comprising:
introducing a dividing channel that crosses the cover substrate and runs around the circumference of the window,
wherein the dividing channel is introduced into the cover substrate.

6. The process of claim 1,
wherein the moving of the cover substrate in the region of the window with simultaneous deformation of the base substrate in a region around the window is effected in such a way that the cover substrate assumes an oblique position relative to the base substrate in the region of the window, and
wherein the oblique position of the cover substrate in the region of the window has an angle between 1 degree and 45 degrees.

7. The process of claim 1,
wherein the moving of the cover substrate in the region of the window is effected by means of a ram that exerts a pressure on the cover substrate in such a way that the base substrate is deformed in a region around the window, where there is optionally provided, opposite the ram, an opposing face against which the base substrate is pressed, and/or
wherein the moving of the cover substrate in the region of the window is effected by means of a ram that exerts a pressure on the base substrate in the region around the window in such a way that the base substrate is deformed in the region around the window, where there is optionally provided, opposite the ram, an opposing face against which the cover substrate is pressed, and/or
wherein the ram and/or the opposing face take(s) the form of a circumferential collar that acts on the respective substrate in the region of the connection region and/or of the contact region, and/or
wherein the ram and/or the opposing face is/are heated.

8. The process of claim 1,
wherein the temperatures of the base substrate and of the cover substrate differ from one another by at least 50 K, and/or
wherein the differing softening temperatures of the base substrate and of the cover substrate differ from one another in such a way that, at the softening temperature of the base substrate and/or at the softening temperature of the cover substrate, the viscosity of the two substrates differs by at least 10^{0.5} Pas,
wherein the base substrate comprises one of the following materials: glass, borosilicate glass, soda-lime glass, alkali metal borosilicate glass, alkali metal borate glass, alkali metal phosphate glass, zinc borate glass, lead-containing glass, vanadate glass, zinc phosphate glass,
wherein the cover substrate especially comprises one of the following materials: glass, aluminosilicate glass, aluminoborosilicate glass, rare earth aluminosilicate glass, alkaline earth metal aluminosilicate glass, glass-ceramic, quartz glass, sapphire, silicon, germanium.

9. The process of claim 1,
wherein the bond strength between the base substrate and the cover substrate is at least 10 MPa,
wherein the coefficient of thermal expansion of the base substrate is between 2×10⁻⁶ K⁻¹ and 10×10⁻⁶ K⁻¹, and/or
wherein the coefficient of thermal expansion of the cover substrate is between 2×10⁻⁶ K⁻¹ and 10×10⁻⁶ K⁻¹, and/or
wherein the absolute value of the difference between the coefficients of thermal expansion of the base substrate and of the cover substrate is less than 5×10⁻⁶ K⁻¹, and/or
wherein the base substrate has a thickness of between 0.02 mm and 5 mm, and/or
wherein the cover substrate has a thickness of between 0.02 mm and 5 mm, and/or
wherein the window in the base substrate has an area of between 0.5 mm×0.5 mm and 50 mm×50 mm.

10. The process of claim 1,
wherein the cover substrate has a surface having an average roughness Rₐ of not more than 15 nm, and/or
wherein the cover substrate has a flatness of less than 20 μm, and/or
wherein the cover substrate has a variation in thickness of less than 5%, and/or
wherein the cover substrate has transmittance for a wavelength between 300 nm and 2500 nm of at least 90%.

11. The process of claim 1,
wherein the base substrate has a multitude of windows that are each formed by an opening within the base substrate, and
wherein the transparent cover substrate is intended for simultaneous coverage of the multitude of windows or wherein a multitude of transparent cover substrates is provided, each of which is intended to cover one or more windows.

12. A process for producing an encapsulated MEMS component, comprising:
providing a carrier substrate having a MEMS component, and
applying and hermetically bonding a composite cap element produced according to claim 1, atop the carrier substrate in such a way that the MEMS component is hermetically sealed between the carrier substrate and the composite cap element.

13. A composite cap element for the encapsulation of a MEMS component, produced according to claim 1.

14. A composite cap element for the encapsulation of a MEMS component, comprising:
a base substrate having at least one window, formed by an opening within the base substrate,
a transparent cover substrate that transparently covers the window in the base substrate,
a hermetic bond between the base substrate and the cover substrate in a connection region formed around the circumference of the window in such a way that the window is hermetically sealed,
wherein the base substrate has a deformation (150) in a region around the window in such a way that the cover substrate has been moved in its position relative to the base substrate, and
wherein the base substrate and the cover substrate have different softening temperatures, wherein the softening temperature of the base substrate is lower than the softening temperature of the cover substrate.

15. The composite cap element of claim 14,
wherein the hermetic bond between the base substrate and the cover substrate is linear, and/or
wherein the hermetic bond between the base substrate and the cover substrate is two-dimensional.

16. The composite cap element of claim 14,
wherein regions of the base substrate are two-dimensional, and/or wherein regions of the transparent cover substrate are two-dimensional, and/or
wherein the transparent cover substrate is in two-dimensional contact with the base substrate within a contact region around the window in order to transparently cover the window in the base substrate, and
wherein the contact region has a width of at least 10 μm, and
wherein the bond between the base substrate and the cover substrate especially has a bond quality index Q of not less than 0.8,
wherein the bond quality index Q is defined as Q=1−(A−G)/A where A denotes the area of the contact region between the base substrate and the cover substrate and G denotes an area within which the distance between the substrates is less than 5 μm.

17. The composite cap element of claim 14, further comprising:
a dividing channel that crosses the cover substrate and runs around the circumference of the window.

18. The composite cap element of claim 14,
wherein the deformation of the base substrate is such that the cover substrate has an oblique position relative to the base substrate in the region of the window, and
wherein the oblique position of the cover substrate in the region of the window in particular has an angle between 1 degree and 45 degrees.

19. The composite cap element of claim 14,
wherein the differing softening temperatures of the base substrate and of the cover substrate differ from one another by at least 50 K,
wherein the base substrate especially comprises one of the following materials: glass, borosilicate glass, soda-lime glass, alkali metal borosilicate glass, alkali metal borate glass, alkali metal phosphate glass, zinc borate glass, lead-containing glass, vanadate glass, zinc phosphate glass,
wherein the cover substrate comprises one of the following materials: glass, aluminosilicate glass, aluminoborosilicate glass, rare earth aluminosilicate glass, alkaline earth metal aluminosilicate glass, glass-ceramic, quartz glass, sapphire, silicon, germanium.

20. The composite cap element of claim 14,
wherein the bond strength between the base substrate and the cover substrate is at least 10 MPa,
wherein the coefficient of thermal expansion of the base substrate is between 2×10⁻⁶ K⁻¹ and 10×10⁻⁶ K⁻¹, and/or
wherein the coefficient of thermal expansion of the cover substrate is between 2×10⁻⁶ K⁻¹ and 10×10⁻⁶ K⁻¹, and/or
wherein the absolute value of the difference between the coefficients of thermal expansion of the base substrate and of the cover substrate is less than 5×10⁻⁶ K⁻¹, preferably less than 2×10⁻⁶ K⁻¹, more preferably less than 1×10⁻⁶ K⁻¹, and/or
wherein the base substrate has a thickness of between 0.02 mm and 5 mm, and/or
wherein the cover substrate has a thickness of between 0.02 mm and 5 mm and/or
wherein the window in the base substrate has an area of between 0.5 mm×0.5 mm and 50 mm×50 mm.

21. The composite cap element of claim 14,
wherein the cover substrate has a surface having an average roughness Rₐ of not more than 15 nm, and/or
wherein the cover substrate has a flatness of less than 20 μm, and/or
wherein the cover substrate has a variation in thickness of less than 5%, of the average thickness across the area of the window, and/or
wherein the cover substrate has transmittance for a wavelength between 300 nm and 2500 nm of at least 90%.

22. The composite cap element of claim 14,
wherein the base substrate has a multitude of windows that are each formed by an opening within the base substrate, and
wherein the transparent cover substrate simultaneously covers the multitude of windows or wherein a multitude of transparent cover substrates is included, each of which covers one or more windows, and
wherein a hermetic bond between the base substrate and the cover substrate around the circumference of each of the windows is included, and
wherein the base substrate has a deformation in a region around each window such that the cover substrates have been moved in their position relative to the base substrate.

23. An encapsulated MEMS component comprising:
a carrier substrate having a MEMS component and
a composite cap element of claim 14, applied and hermetically bonded atop the carrier substrate in such a way that the MEMS component is hermetically sealed between the carrier substrate and the composite cap element.
